(19) United States
(12) Patent Application Publication
(10) Pub. No.: US 2010/0148305 A1
(43) Pub. Date: Jun. 17, 2010

(54) Semiconductor Device and Fabricating Method Thereof

(76) Inventor: Jong Yong Yun, Seoul (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/628,043

(22) Filed: Nov. 30, 2009

(30) Foreign Application Priority Data
Dec. 12, 2008 (KR) 10-2008-0126588

(51) Int. Cl. H01L 29/92; H01L 21/02

(52) U.S. Cl. 257/532; 438/381; 257/E29.342; 257/E21.008

(57) ABSTRACT

A semiconductor device and fabricating method thereof are disclosed. The present invention includes an insulating layer on a semiconductor substrate, a contact plug in and protruding from the insulating layer, and a capacitor on the insulating layer and the exposed contact plug, having a dome shape.

This application claims the benefit of Korean Patent Application No. 10-2008-0126588, filed on 12 Dec. 2008, which is hereby incorporated by reference as if fully set forth herein.

### BACKGROUND OF THE INVENTION

1. Field of the Invention

The present invention relates to a semiconductor device, and more particularly, to a capacitor in a semiconductor device and method of fabricating the same.

2. Discussion of the Related Art

Recently, the ongoing merged memory logic (MML) device is configured in a manner that a memory cell array unit and analog or peripheral circuitry are integrated together on one chip. The considerable enhancement of multimedia functions is attributed to MML, and enables high integration and speed of a semiconductor device effectively. And, many efforts are being made to research and develop a capacitor of high capacity for analog circuitry that requires high-speed operations.

FIG. 1 shows a metal-insulator-metal (MIM) capacitor according to a related art. Referring to FIG. 1, a capacitor in an MIM structure consists of a lower metal 10, an insulating layer 20 and an upper metal 30, which are sequentially stacked on one another.

This MIM capacitor has small specific resistance and does not have parasitic capacitance attributed to internal depletion. Hence, the MIM capacitor is mainly used for a semiconductor device of high performance. The MIM capacitor has a structure having a uniform size, and its capacitance depends on the size.

### SUMMARY OF THE INVENTION

Accordingly, the present invention is directed to a semiconductor device and method of fabricating the same that substantially obviate one or more problems due to limitations and disadvantages of the related art.

An object of the present invention is to provide a capacitor in a semiconductor device and a method of fabricating the same, by which a sufficient capacitance can be implemented through a relatively small size capacitor.

Additional advantages, objects, and features of the invention will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose of the invention, as embodied and broadly described herein, a semiconductor device according to the present invention includes an insulating layer on a semiconductor substrate, a contact plug in and protruding from the insulating layer, the contact plug being partially exposed, and a capacitor on the insulating layer and the exposed contact plug, having a dome shape.

In another aspect of the present invention, a method of fabricating a capacitor includes the steps of forming a contact plug in an insulating layer on a semiconductor substrate, exposing an upper portion of the contact plug by etching a part of the insulating layer adjacent to the upper portion of the contact plug, and forming a dome-shaped capacitor on the insulating layer and the exposed contact plug.

Accordingly, the present invention provides the following effects and/or advantages.

First of all, the present invention increases a contact cross-sectional size by forming a lower contact plug in a dome shape on an exposed insulating layer, thereby increasing capacitance. Moreover, the present invention is able to implement a capacitor in a relatively small area.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle(s) of the invention. In the drawings:

FIG. 1 is a cross-sectional diagram of a capacitor according to a related art; and

FIGS. 2 to 6 are cross-sectional diagrams for a semiconductor device process according to embodiments of the present invention.

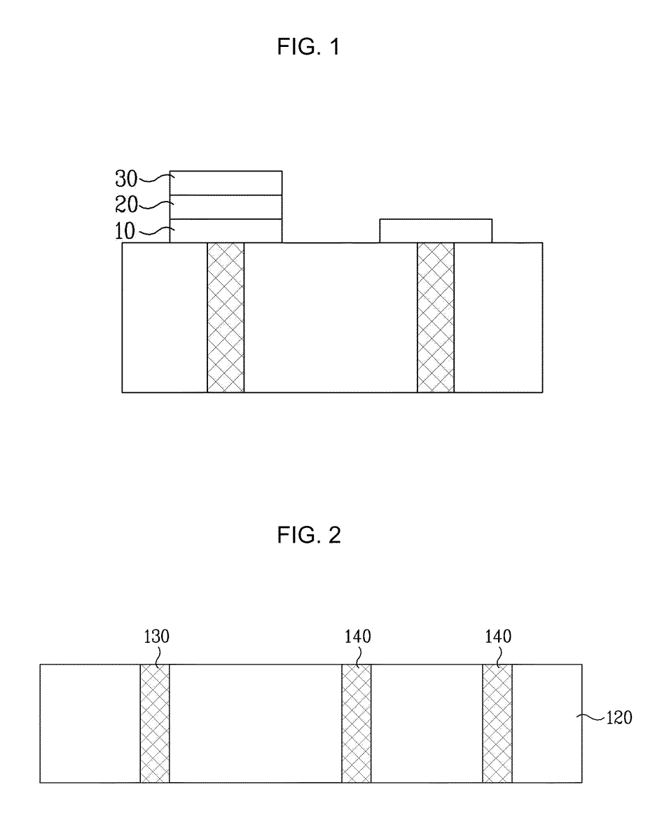

### DETAILED DESCRIPTION OF THE INVENTION

Reference will now be made in detail to preferred embodiments of the present invention, examples of which are illustrated in the accompanying drawings. Wherever possible, the same reference numbers will be used throughout the drawings to refer to the same or like parts.

FIG. 6 shows a structure of a semiconductor device according to an embodiment of the present invention.

Referring to FIG. 6, a capacitor according to the present invention includes an insulating layer 120 on a semiconductor substrate 100, a protruding contact plug 130 in the insulating layer 120, one or more non-protruding contact plugs 140, a capacitor 200 formed on the insulating layer 120 including the protruding contact plug 130, and a metal line 190.

In this case, the protruding portion of the protruding contact plug 130 is exposed by the insulating layer 120 adjacent to the protruding contact plug 130 being etched so that its upper surface is lower than the portion(s) adjacent to the non-protruding contact plugs 140.

Hence, the protruding contact plug 130 can “bend” the capacitor 200 in accordance with an exposed height of the protruding contact plug 130.

Since a lower electrode (e.g., conductive layer 160), dielectric layer 170 and upper electrode (e.g., conductive layer 180) are deposited on the exposed protruding contact plug 130, they have a bent or curved structure provided on the insulating layer 120.

In particular, since the capacitor 200 is formed in a dome shape, an area provided by the dome-shape structure is greater than that of a general capacitor formed flat. Therefore, a contact surface area is increased to raise capacitance.

In this case, the protruding contact plug 130 and the non-protruding contact plug 140 can comprise one or more of a doped polysilicon layer, a titanium layer, a tantalum layer, a metal silicide layer (e.g., titanium silicide, tungsten silicide, molybdenum silicide, cobalt silicide, nickel silicide, etc.), a metal nitride layer (e.g., titanium nitride, tantalum nitride, tungsten nitride, etc.), an aluminum or aluminum alloy layer (e.g., Al alloyed with up to 4 wt. % of Ti or Cu, and/or with up to 1 wt. % of Si), and a tungsten layer. The contact plug 140 can be electrically connected to a source of a MOS transistor or a conductive pad electrically connected to the source.

The lower electrode 160 and the upper electrode 180 can include a TiN layer, a WN layer or a TaN layer, or any of the other conductive materials described herein (e.g., for the contact plugs 130 and 140), as a single layer or a multi-layered laminate (e.g., TiN-on-Ti, TaN-on-Ta, a TiN/Ti/Al alloy/TiN/Ti stack, etc.). The lower electrode 160 can be formed by CVD (Chemical Vapor Deposition), ALD (Atomic Layer Deposition) and/or SFD (Sequential flow deposition).

The dielectric layer 170 can include a high-k layer such as hafnium oxide, zirconium oxide, lanthanum oxide, or a high-k layer containing nitrogen (e.g., silicon nitride, silicon oxynitride, etc.).

A method of fabricating a capacitor in a semiconductor device according to embodiments of the present invention is explained with reference to FIGS. 2 to 6 as follows.

Referring to FIG. 2, an insulating layer 120 (sometimes referred to as an “insulating interlayer”) is formed on a semiconductor substrate (not shown in the drawing). Besides, a conductive layer (not shown in the drawing), e.g., a MOS transistor, a conductive pad, a bitline and the like, can be formed on the semiconductor substrate prior to forming the insulating layer 120.

Subsequently, contact plugs 130 and 140 are formed in prescribed portions of the insulating layer 120 by one or more well-known methods. For instance, contact or via holes corresponding to the contact plugs 130 and 140 can be formed by photolithographic patterning and dry (plasma) etching, one or more conductive materials may be blanket-deposited onto the insulating layer 120 and into the contact/via holes by sputtering, CVD, ALD, etc., and the excess conductive material(s) outside the contact/via holes may be removed by chemical mechanical polishing (CMP or etchback. The contact plugs 130 and 140 may comprise a doped polysilicon layer, an aluminum or aluminum alloy layer (e.g., as described herein), a copper layer, or a tungsten layer, any of which may further include an adhesive, barrier and/or seed layer (e.g., including titanium, tantalum, titanium silicide, tungsten silicide, molybdenum silicide, cobalt silicide, nickel silicide, titanium nitride, tantalum nitride, tungsten nitride, laminates or bilayers thereof, such as TiN-on-Ti, TaN-on-Ta, Cu-on-TaN-on-Ta, etc.) along the sidewall(s) of the contact/via holes.

The contact plugs 140 can be electrically connected to a source/drain terminal (e.g., a source) and/or a gate of an MOS transistor, or a conductive pad electrically connected to the source/drain terminal or gate. Alternatively, contact plugs 140 can be electrically connected to an underlying or overlying metallization structure.

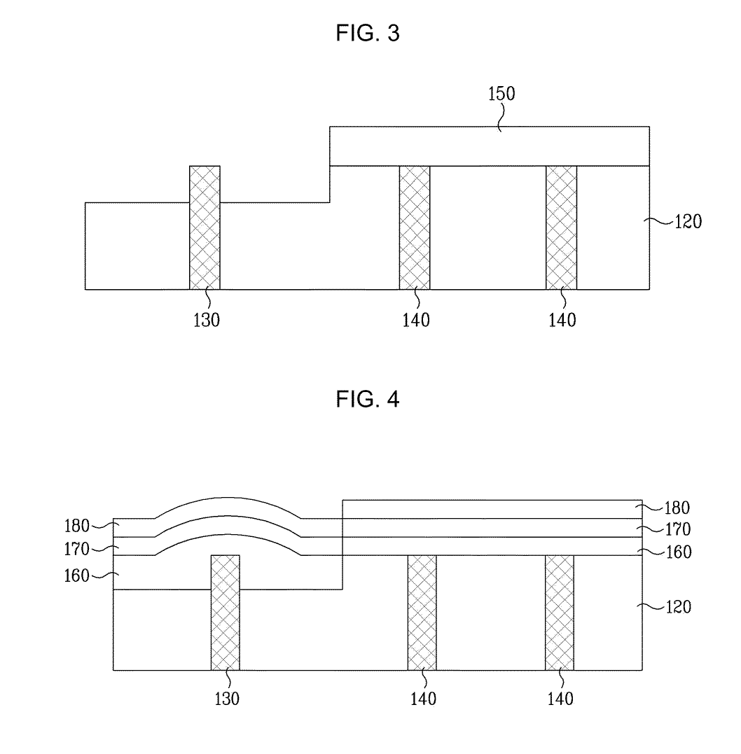

Referring to FIG. 3, a photoresist pattern 150 is formed on the insulating layer 120. An upper portion of the insulating layer 120 adjacent to the contact plug 130 is etched using the photoresist pattern 150 as an etch mask.

If so, a protruding contact plug 130 is exposed over the etched insulating layer 120. In this case, a height of the protruding contact plug 130 can correspond to or be adjusted according to a desired or predetermined extent of bending of the capacitor that will be formed in subsequent processing.

Referring to FIG. 4, a first conductive layer 160 is formed on the insulating layer 120, to form a lower electrode over the semiconductor substrate 100.

The conductive layer 160 can include, among other conductive materials disclosed herein, a TiN layer, a WN layer or a TaN layer. The conductive layer 160 can be formed by CVD (Chemical Vapor Deposition), ALD (Atomic Layer Deposition) and/or SFD (Sequential flow deposition).

A capacitor dielectric layer 170 is then formed on the lower electrode conductive layer 160.

The dielectric layer 170 can include a high-k layer as a hafnium oxide layer, a zirconium oxide layer, a lanthanum oxide layer or a high-k layer containing nitrogen (e.g., silicon nitride, silicon oxynitride, etc.).

A conductive layer 180 is then formed on the dielectric layer 170 to form an upper electrode thereover. In this case, the conductive layer 180 can comprise the same material as that of the conductive layer 160.

Since the conductive layer 160, the dielectric layer 170 and the conductive layer 180 are formed over the protruding contact plug 130 projected below, they are formed in a convex or bent shape.

In particular, since conductive layer 160, the dielectric layer 170 and the conductive layer 180 are provided over the protruding contact plug 130 and have a dome shape, they can provide a contact surface area greater than that of a general flat or planar type capacitor.

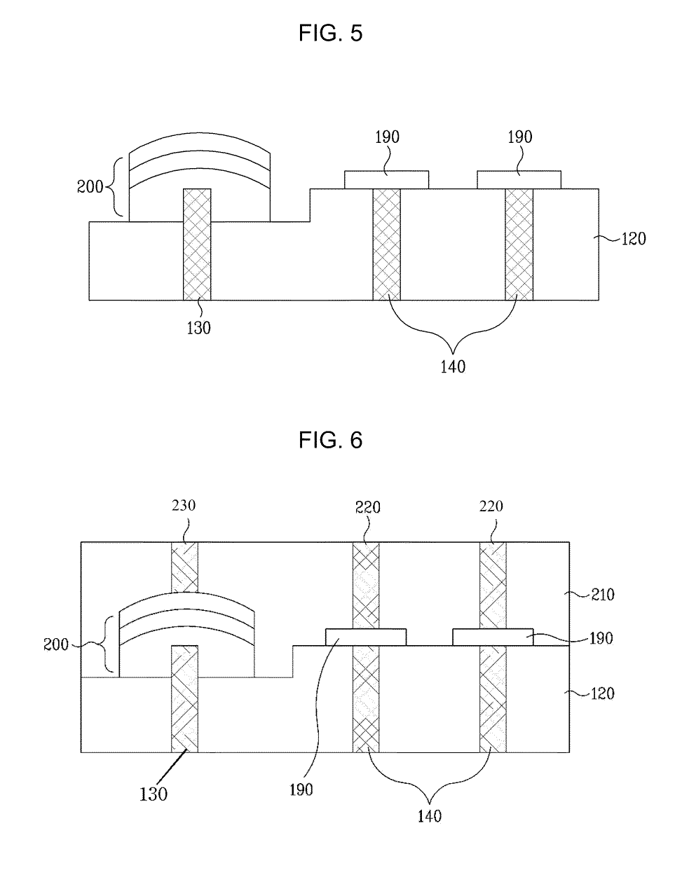

Referring to FIG. 5, the conductive layer 160, the dielectric layer 170 and the conductive layer 180 are patterned (e.g., by photolithography) and etched (e.g., by dry chemical etching or reactive ion etching) to form a MIM capacitor 200. Thereafter, a metal layer can be deposited, photolithographically patterned, and etched as described herein to form a metal line 190. Alternatively, if the conductive layer 160 can be used for metallization (e.g., interconnections between metal lines in another layer of metallization, or local interconnects between nearby transistor terminals, etc.), then one may selectively etch dielectric layer 170 (e.g., relative to conductive layer 160), optionally strip any photoresist mask used to pattern conductive layer 180 and dielectric layer 170, then form a second photoresist pattern (e.g., by photolithography) as an etching mask over the metal layer used to form metal lines 190. As a result, in one embodiment, the metal lines 190 may comprise the same materials, in the same sequence, as the lower electrode of capacitor 200. Therefore, a MIM capacitor 200 and a plurality of metal lines 190 are formed.

Referring to FIG. 6, an etch stop layer (not shown in the drawing) is formed over the semiconductor substrate 100 including the MIM capacitor 200 and the metal lines 190. In this case, the etch stop layer may comprise SiN, and may have a thickness of 50-500 Å, for example.

A second insulating interlayer 210 is then formed on the etch stop layer.

Subsequently, holes for exposing the MIM capacitor 200 and the metal line 190 are formed in the second insulating interlayer 210. The holes are filled with tungsten layers 220 and 230. As described above with regard to contacts 130 and 140, next-level contacts 220 and 230 may comprise aluminum, an aluminum alloy, or copper, and adhesive, barrier and/or seed layers may be formed in the next-level contact holes prior to the bulk metal. CMP is then performed on the substrate to remove excess metal from outside the contact holes.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A semiconductor device comprising:
an insulating layer on a semiconductor substrate;
a contact plug in and protruding from the insulating layer; and
a capacitor on the insulating layer and the protruding contact plug, having a dome shape.

2. The semiconductor device of claim 1, wherein the capacitor comprises a conductive lower electrode, a dielectric layer, and a conductive upper electrode over the insulating layer.

3. The semiconductor device of claim 2, wherein each of the lower electrode and the upper electrode comprises doped polysilicon, titanium, tantalum, tungsten, a metal silicide, a metal nitride, aluminum or an aluminum alloy.

4. The semiconductor device of claim 2, wherein each of the lower electrode and the upper electrode comprises a metal nitride layer selected from the group consisting of a TiN layer, a TaN layer and a WN layer.

5. The semiconductor device of claim 2, wherein the dielectric layer comprises a high-k layer selected from the group consisting of a hafnium oxide layer, a zirconium oxide layer, a lanthanum oxide layer and a high-k layer containing nitrogen.

6. The semiconductor device of claim 5, wherein the high-k layer containing nitrogen comprises silicon nitride or silicon oxynitride.

7. The semiconductor device of claim 1, wherein the capacitor is bent to an extent corresponding to a height of the contact plug protruding from the insulating layer.

8. The semiconductor device of claim 1, further comprising a plurality of non-protruding contacts in the insulating layer and a plurality of metal lines on the insulating layer in electrical contact with the plurality of non-protruding contacts.

9. The semiconductor device of claim 8, wherein a portion of the insulating layer under the capacitor has a thickness less than a portion of the insulating layer under the plurality of metal lines.

10. A method of fabricating a capacitor, comprising the steps of:
forming a contact plug in an insulating layer on a semiconductor substrate;
exposing an upper portion of the contact plug by etching part of the insulating layer adjacent to the upper portion of the contact plug; and
forming a dome-shaped capacitor on the insulating layer and the exposed contact plug.

11. The method of claim 10, wherein forming the capacitor comprises:
forming a lower conductive layer on the exposed contact plug;
forming a dielectric layer on the lower electrode conductive layer; and
forming an upper conductive layer on the dielectric layer.

12. The method of claim 11, wherein each of the lower conductive layer and the upper conductive layer comprises doped polysilicon, titanium, tantalum, tungsten, a metal silicide, a metal nitride, aluminum or an aluminum alloy.

13. The method of claim 11, wherein each of the lower conductive layer and the upper conductive layer comprises a metal nitride layer selected from the group consisting of a TiN layer, a TaN layer and a WN layer.

14. The method of claim 11, wherein the dielectric layer comprises a high-k layer selected from the group consisting of a hafnium oxide layer, a zirconium oxide layer, a lanthanum oxide layer and a high-k layer containing nitrogen.

15. The method of claim 14, wherein the high-k layer containing nitrogen comprises silicon nitride or silicon oxynitride.

16. The method of claim 10, wherein the capacitor is bent to an extent corresponding a height of the contact plug protruding from the insulating layer.

17. The method of claim 10, further comprising:
forming a plurality of non-protruding contacts in the insulating layer; and
forming a plurality of metal lines on the insulating layer in electrical contact with the plurality of non-protruding contacts.

18. The method of claim 10, wherein etching the part of the insulating layer adjacent to the upper portion of the contact plug that comprises etching a partial thickness of a predetermined area of the insulating layer.

19. The method of claim 18, wherein the partial thickness of the insulating layer that is etched is equal to at least 50% of the thickness of the capacitor.

20. The method of claim 19, wherein the partial thickness of the insulating layer that is etched is not greater than the thickness of the capacitor.
